(19) United States
(12) Patent Application Publication
(10) Pub. No.: US 2021/0364576 A1
(43) Pub. Date: Nov. 25, 2021

(54) Use of Standing Wave Ratio Measurements for Interconnect Testing

(71) Applicant: United States Department of Energy, Washington, DC (US)

(72) Inventor: Travis Z. Fullem, West Mifflin, PA (US)

(73) Assignee: United States Department of Energy, Washington, DC (US)

(21) Appl. No.: 17/326,438

(22) Filed: May 21, 2021

Related U.S. Application Data
(60) Provisional application No. 63/028,862, filed on May 22, 2020.

(51) Int. Cl. G01R 31/54; G01R 31/66

(52) U.S. Cl. CPC G01R 31/54; H04B 17/103; G01R 31/66

(57) ABSTRACT

Disclosed is a method of determining electrical continuity of electrical interconnects, the method comprising the steps of measuring a first standing wave ratio value when the electrical interconnects are disconnected, measuring a second standing wave ratio value when the electrical interconnects are connected, and comparing the first standing wave ratio value to the second standing wave ratio value, wherein electrical continuity is positively determined when the second standing wave ratio value is much larger than the first standing wave ratio value.

### CROSS-REFERENCE TO RELATED APPLICATION

This application claims priority to U.S. Provisional Patent Application 63/028,862 filed on May 22, 2020, which is hereby incorporated by reference in its entirety.

### GOVERNMENT INTEREST STATEMENT

This invention was made with government support under DOE Contract No. DE-NR0000031. The government has certain rights in the invention.

### FIELD

The present subject matter relates generally to a method of testing electronic systems for the purpose of confirming electrical continuity.

### BACKGROUND

Certain aspects of present subject matter relate in general to a method for determining whether electrical continuity exists between two or more electrical nodes, based on standing wave ratio measurements made at an electrical node. Many electronic systems include multiple circuit boards, and the electrical interconnects which allow communication between these circuit boards often include mated connectors. For many systems, verification of electrical continuity through the conduction paths in the connectors is necessary prior to placing the system in service. In some cases, the ability of the system to function may serve as verification. This is not practical, however, in cases where testing every possible function of the system is required.

Certain aspects of the present subject matter may be used to confirm electrical continuity though the interconnects without placing the system in service. In some cases, physical access to one or more of the electrical interconnects may be restricted, resulting in limited options for performing electrical tests of the connection paths. The present subject matter is of utility for, but not limited to, testing interconnects in this situation. Therefore, the present subject matter serves to test the electrical continuity between electrical interconnects without having to place a system into service and tediously exercise all functions of the system or to access circuit nodes on both sides of the interconnects which would involve burdensome physical tasks to test otherwise inaccessible interconnects.

### SUMMARY

In one aspect of the present subject matter, a system for determining electrical continuity of electrical interconnects, the system including a first electronic device having a first electrical connector, a second electronic device having a second electrical connector configured to be electrically connected to the first electrical connector to establish electrical continuity, a standing wave ratio meter connected to one of the first electronic device and the second electronic device, a radio frequency generator connected to the standing wave ratio meter, and a controller including a processor and a memory storage device.

Another aspect of the present subject matter includes a method of determining electrical continuity of electrical interconnects, the method including the steps of measuring a first standing wave ratio value when the electrical interconnects are disconnected, measuring a second standing wave ratio value when the electrical interconnects are connected, and comparing the first standing wave ratio value to the second standing wave ratio value, wherein electrical continuity is positively determined when the second standing wave ratio value is much larger than the first standing wave ratio value.

In another aspect, a method of determining electrical continuity of electrical interconnects, the method including the steps of measuring a first standing wave ratio value when the electrical interconnects are disconnected, measuring a second standing wave ratio value when the electrical interconnects are connected, and comparing the first standing wave ratio value to the second standing wave ratio value, wherein electrical continuity is positively determined when the second standing wave ratio value is much larger than the first standing wave ratio value, and there is access to only one end of a conducting path between the electrical interconnects.

### BRIEF DESCRIPTION OF THE DRAWINGS

A description of the present subject matter including various embodiments thereof is presented with reference to the accompanying drawings, the description not meaning to be considered limiting in any matter, wherein:

FIG. 1A illustrates a diagram of a standing wave ratio meter and radio frequency generator attached to an exemplary embodiment of disconnected system of the present subject matter;

FIG. 1B illustrates a diagram of a standing wave ratio meter and radio frequency generator attached to an exemplary embodiment of a connected system of the present subject matter;

FIG. 2 illustrates a diagram of an exemplary method of the present subject matter; and

FIG. 3 illustrates a diagram of another exemplary method of the present subject matter.

### DETAILED DESCRIPTION

Throughout the discussion below, use of the terms “about” and “approximately” are used to indicate engineering tolerances which would be well understood by a person of ordinary skill in the art for any particular application or embodiment. The embodiments disclosed herein relate to a system and method for testing of electronic systems. More particularly, disclosed herein are various embodiments of methods and systems for confirming electrical continuity of two or more electrically interconnected elements. In this context, “electrical continuity” will be recognized by those of skill in the art as providing a continuous conducting path. In some embodiments, one or more of the electrically interconnected elements may be difficult to access physically.

Certain aspects of present subject matter use standing wave ratio (SWR) measurements to test the continuity of electrical interconnects. Some embodiments address this problem by considering the conductive paths of electrically interconnected elements to be antennas and testing an SWR of the interconnected elements under various conditions. Comparing the measured value of the SWR under specified conditions can reveal if one or more electrically interconnected elements have formed a valid, continuous, conducting path. Other methods of testing the electrical continuity of electrically interconnected elements require that test equipment be simultaneously connected to more than one interconnected element, which can be burdensome when one or more such elements is difficult to access physically. Unlike other methods of using SWR to test continuity of conductive paths, which determine the location of a known fault, the present subject matter determines whether continuity exists at a specific known location (e.g., a connector). In some embodiments, the method requires physical access to only one of the electrically interconnected elements.

The relative strength of the reflected wave can be quantified by measuring the standing wave ratio (SWR), which is defined as the following ratio:

$$SWR = \frac{{V}_{max}}{{V}_{min}}$$

where V is the measured voltage. Alternatively, SWR can be measured as the ratio of the impedance of the source Z_{source} (e.g., the impedance of the transmitter) to the impedance of the load Z_{load} (the impedance of the antenna).

SWR measurements can be performed at a given frequency for the purpose of adjusting an antenna to optimize the antenna for use over a fixed limited range of frequencies. In checking the SWR in antennas intended to broadcast a signal, for example, one or more transmitters can be connected to an antenna using a transmission line (a coaxial cable, for example) wherein reflections of the transmitted signal occur from the antenna. A low SWR typically indicates a relatively low reflection of a transmitted signal, while a large SWR typically indicates a large reflection of a transmitted signal. Avoiding large reflections back to the transmitter is desirable for two reasons: energy reflected back to the transmitter is not available for transmission to the air (which undermines the objective of transmitting a signal), and excessively large reflections could damage the transmitter.

Antennas can be designed to be used with specific frequency bands, with their physical dimensions chosen based on the wavelength of the signal of interest. One example of an antenna design is for the antenna to be a conductor with a length of ¼ of a transmitted wavelength. The frequency (f) and wavelength (λ) are related by the equation below:

$$f = \frac{c}{λ}$$

where c is the speed of light (˜3×10⁸ m/s). Therefore, a ¼ wavelength antenna intended for use at, for example, 144 MHz would have a length of 0.52 m. This length is exemplary only, as other wavelength fractions and/or frequencies can be used without departing from the scope of the present subject matter. In the present subject matter, the system in both its disconnected state and in its connected state approximates an antenna for which an SWR can be measured.

In certain embodiments, the frequency at which a minimum SWR is observed is a function of the length of the electrical path between the electrical device and the point at which the RF signal input connects to the electrical device. In certain examples, the frequency (f) at which the SWR value will be a minimum for the case in which connector “A” is disconnected can be estimated mathematically, based on the length of the conducting path length (PL) between a test connector and connector “A”, using the equation below:

f=c/(4×(PL))

where c is the speed of light (or alternatively the velocity of propagation of a signal on the circuit card can be used, if it is known) and PL is the circuit conducting path length. This assumes that the circuit trace approximates an antenna with its path length is equal to ¼ of the wavelength of the signal.

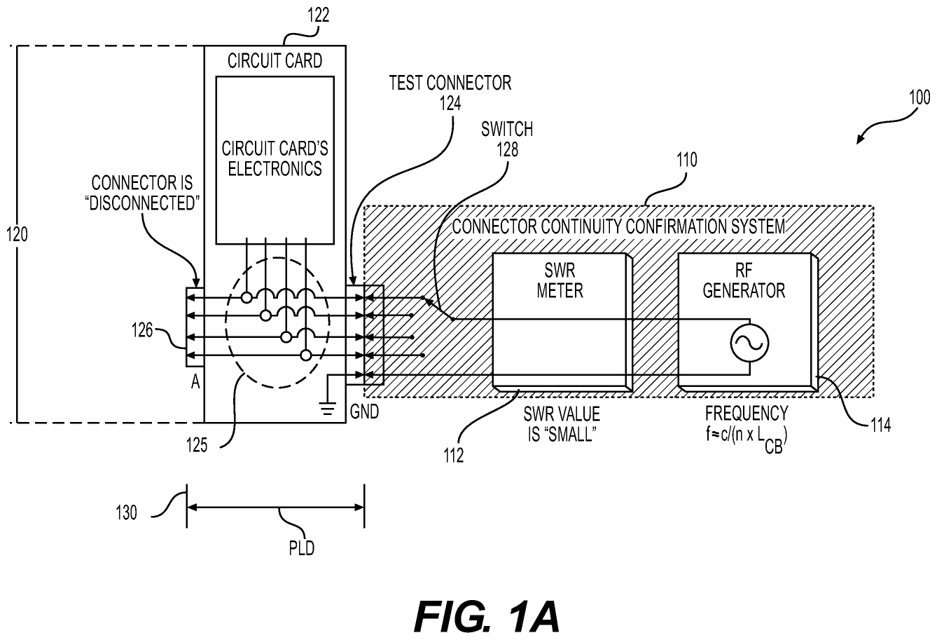

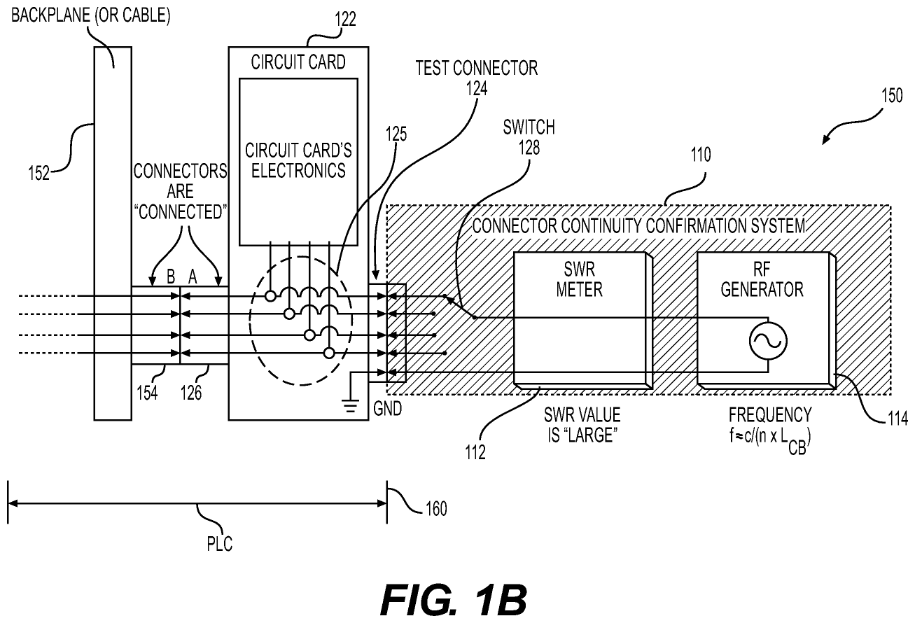

FIGS. 1A and 1B illustrate exemplary embodiments of systems disclosing the present subject matter. FIG. 1A illustrates an exemplary disconnected system 100, and FIG. 1B illustrates an exemplary connected system 150. In these exemplary embodiments, certain elements of systems 100 and 150 are treated as antennas, as any conductor will function as an antenna and will approximate a good antenna at some frequencies (i.e., it will have resonant frequencies) the value of which depends on the physical dimensions of the conductor. In the embodiments shown in FIGS. 1A and 1B, for example, a conductive path in circuit 120 can be treated as an antenna, with the electrical path length being the distance from test connector 124 to connector A 126, which forms disconnected path length PL_{D} 130 in disconnected system 100 and connected path length PL_{C} 160 in connected system 150. In FIG. 1A, a continuity tester 110 connects with a circuit under test 120 (generically referred to as circuit 120) via test connector 124. In the exemplary embodiment shown, continuity tester 110 includes radio frequency (RF) generator 112 and SWR meter 114. Circuit 120 includes circuit card 122, which is in electrical connection with test connector 124 and connector A 126. Circuit 120 in the configuration shown has connected path length PL_{D} 130. Although circuit 120 only shows circuit card 122, circuit 120 can include other electrical devices (in place of and/or in addition to) circuit card 122 without departing from the scope of the present subject matter. The electrical devices can be any type of electrical device or component known in the art, including but not limited to a circuit board, a circuit card, a backplane, or similar devices. Though not shown in FIG. 1A, certain exemplary embodiments can also include a controller including a processor and a memory storage device.

FIG. 1B illustrates an exemplary electrical device in a connected state shown, for example, as connected system 150. In this exemplary embodiment a circuit under test 120 (generically referred to as circuit 120) (see, e.g., FIG. 1A) electrically connects to backplane 152 via an electrical connection between connector A 126 and connector B 154. Circuit 120 in this configuration has connected path length PL_{C} 160. The type of electrical interconnection is not limited to what is shown. The electrical devices may be electrically interconnected using any method known in the art. In some embodiments, for example, a first electrical device (circuit card 122 for example) may be directly electrically connected to a second electrical device (backplane 152 for example) to establish electrical continuity. In some embodiments, the first electrical device can be physically mated to the second electrical device. The mating of the first and second electrical devices may occur when a male connector on the first electrical device is inserted into a female connector on the second electrical device, and/or when a male connector on the second is inserted into a female connector from the first device. In other embodiments, the mating of the first and second electrical devices may be indirect, for example when a conductive cable is electrically connected to both the first and second electrical devices. In yet other embodiments, the mating of the first and second electrical devices may occur when both the first and second electrical devices have male or female connectors, and each are plugged into corresponding male or female connectors on a backplane or other electrical device.

In the exemplary embodiment of FIG. 1B, connected system 150 is shown connected to backplane 152, but can include other electrical devices (in place of and/or in addition to) backplane 152 without departing from the scope of the present subject matter. The electrical devices can be any type of electrical device or component known in the art, including but not limited to a circuit board, a circuit card, a backplane, or similar devices. In some embodiments, circuit 120 connects to electrical device 152 via connectors A and B 126/154. In other embodiments, mating with device 152 can be via a conductive cable (not shown) that electrically connects system 100 with device 152 to form connected system 150. In certain exemplary embodiments this can be via a connection between circuit 120 and device 152. In yet other embodiments, this connection can occur when a component of system 100 and second device 152 have male or female connectors and each are plugged into corresponding male or female connectors of device 152.

In certain exemplary embodiments, device 152 is a backplane. Generally described, a backplane is an electronic circuit board containing circuitry and/or slots (or sockets, or connectors) into which additional electronic devices (normally found on other circuit boards or cards) can be interconnected. As will be recognized by those of skill in the art, a backplane can be a circuit board containing circuitry and/or slots, sockets, or connectors into which multiple electrical devices can be connected. Functionally, a backplane operates as an interface between these devices and the other parts of a system. Backplanes can have connectors into which the edge connectors of circuit boards are inserted and have interconnects for providing electrical contact with circuitry on the circuit boards. In certain embodiments, backplanes include electrical conductors which provide interconnection paths to a plurality of connectors on the backplane, and these serve as communication pathways between multiple boards. An example of such an arrangement is the pins on the P1/J1 connectors on a VME backplane (see, e.g., “IEEE Standard for a Versatile Backplane Bus: VME Bus” (IEEE Standard 1014-1987) (R2008) and “American National Standard for VME64” (ANSI/VITA 1-1994 (S2011)). In these situations continuity testing can be performed by checking for the presence of the expected conditions as verification of proper backplane performance. Such tests are also not well suited to verification of user defined pins with arbitrary use and interconnections which can vary from system to system.

In other exemplary embodiments, backplanes can include electrical conductors which provide interconnection paths to at least one connector on the opposite side of the backplane to serve as a communication pathway to either a circuit card located on the opposite side of the backplane or to cabling which provides interconnection to circuitry which is remotely located. An example of such an arrangement is the user defined pins on the P2/J2 connectors on a VME backplane (see, e.g., IEEE Standard 1014-1987 (R2008) and ANSI/VITA 1-1994 (S2011)). The use of a backplane often results in one or more of the electrical devices connected to the backplane and/or the backplane itself to be difficult to access physically. In some cases, physical access to the rear of the backplane may be restricted resulting in limited options for performing electrical tests of the connection paths through the backplane. Certain aspects of the present subject matter are of utility for, but not limited to, testing interconnections in this situation.

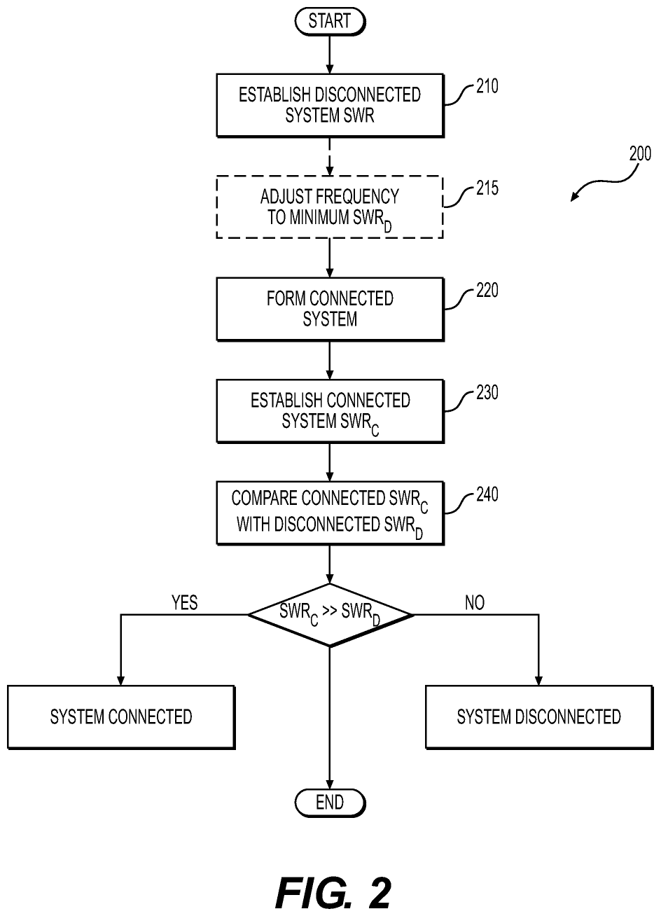

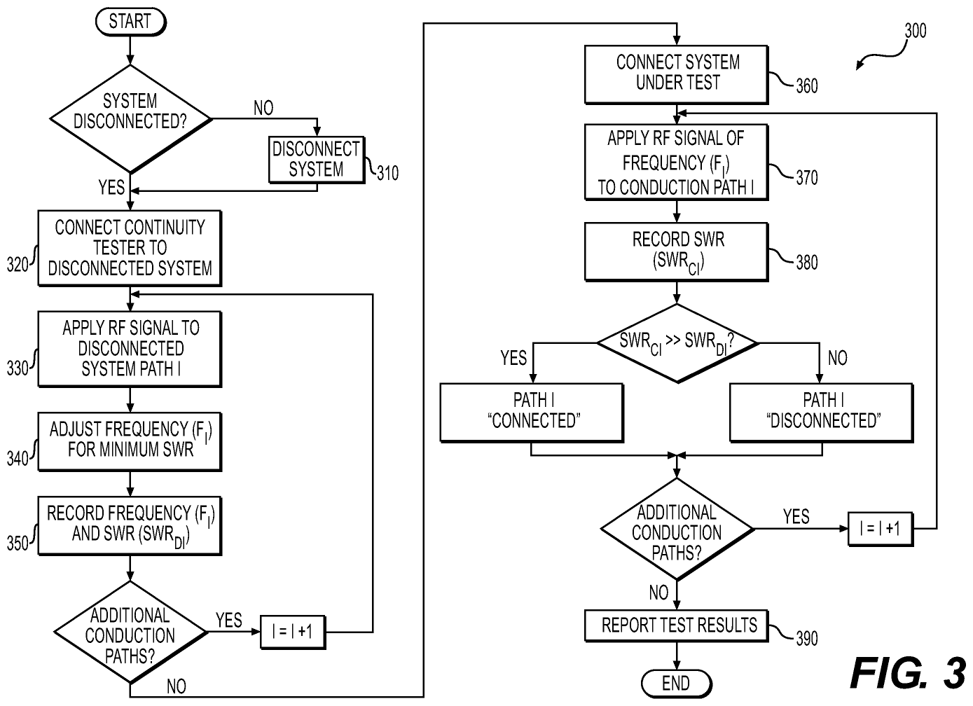

FIGS. 2 and 3 illustrate exemplary embodiments of present subject matter disclosing new applications of SWR measurements used to determine the status (“disconnected” or “connected”) of a connector, electrical device, and/or system. The methods disclosed below are independent of the technique used for measuring SWR. Measurements of SWR can be performed, for example, using a standalone SWR meter connected between a transmitter and a circuit. Radio transmitters (generically referred to as RF generators) are usually connected to an antenna using a transmission line, and reflections of a transmitted signal occur from the antenna. Alternatively, a device known as an antenna analyzer (which includes both a low power transmitter and an SWR meter) can be connected to a circuit. These are examples only, as any SWR meter and/or antenna analyzer known to those of skill in the art can be used without departing from the scope of the present subject matter.

FIG. 2 illustrates an exemplary embodiment of a method 200 for testing the continuity of electrical interconnects. Method 200 contemplates determining if two or more electrical devices have electrical continuity when interconnected. The electrical devices may be any type of electrical device or component known in the art, including but not limited to a circuit board, a circuit card, backplanes, or similar devices. In the exemplary methods used with the embodiments of FIGS. 1A and 1B, for example, certain elements of systems 100 and 150 are treated as antennas, as any conductor will function as an antenna and will approximate a good antenna at some frequencies (i.e., it will have resonant frequencies) the value of which depends on the physical dimensions of the conductor. In certain embodiments, if connector 126 is connected to another device (via connector 154, for example), the electrical length of the conducting path changes (due to the added length of the mating connector and its associated wiring), which changes the resonant frequency. Therefore, the resonant frequency of the conducting path in a connected state differs from the resonant frequency of the conducting path length of circuit card 122 in a disconnected state. If SWR measurements are performed for both cases (“disconnected” and “connected”) at the same frequency, different SWR values will be observed if continuity exists through the circuit path of circuit card 122 and the connected system 150. In still other embodiments, test connectors with a plurality of conductors may also include a switch 128 to allow testing of a plurality of conductors individually.

In certain embodiments, method 200 includes step 210. Step 210 involves establishing a disconnected SWR when the electrical devices are not connected. An exemplary embodiment of disconnected electrical system is illustrated FIG. 1A, discussed above. In some embodiments, step 210 optionally includes being provided the SWR of disconnected system 100. In such embodiments, the disconnected SWR may be provided by an earlier user of method 200 who recorded the disconnected SWR. Alternatively, the disconnected SWR can be provided by the technician or engineer who originally installed or assembled disconnected system 100, i.e., the disconnected SWR may be measured during the initial production of disconnected system 100 and recorded for later use in testing the electrical continuity. In some embodiments, the disconnected SWR may be measured when starting a testing cycle. Such a measurement would include disconnecting the electrical device(s), acquiring the SWR measurement of disconnected system 100 for example, and, optionally, recording the disconnected SWR measurement for present or future use.

Certain embodiments optionally include step 215 by finding a frequency where the SWR is minimized for disconnected system 100. SWR measurements are taken as the input frequency is adjusted until a target SWR is achieved (typically between 1 and 2) in circuit 120 and/or disconnected system 100. In these embodiments the frequency of the signal inputted to disconnected system 100 is adjusted until the disconnected SWR is at a minimum (typically in the range of 1 to approximately 2) such that circuit 120 and/or disconnected system 100 appears to be a matched antenna for the frequency input to disconnected system 100. In these embodiments, a frequency is selected to minimize the SWR value when circuit card 122 and/or circuit 120 is unseated (connectors A and B 126/154 are not mated) (e.g., there is a lack of electrical continuity between connectors A and B 126/154), with connector A 126 electrically connected to the circuit card 122 and/or circuit under test 120. (See, e.g., FIG. 1A). This indicates that card 122 and/or circuit 120 is approximately a matched antenna for the selected frequency (e.g., the electrical path length on the circuit card PL_{D} (also referred to as the conducting path length) is approximately ¼ of the wavelength (or other multiple) of the signal produced by RF generator 114) in disconnected system 100. When circuit card 122 is seated (connectors A and B 126/154 are mated) (e.g., there is electrical continuity between connectors A and B 126/154), it forms connected system 150. In this configuration the connected conducting path PL_{C} 160 will be increased compared to the disconnected conducting path length PL_{D} 130, and therefore will not be a matched antenna for the selected frequency when card 122 is connected to device 152. The change in conducting path length depends on the design of 152. In certain embodiments, a path length change of one inch (from 14 inches to 15 inches, for example) in a circuit input with a radio frequency having a wavelength of approximately 2 meters is enough to detect a change in SWR. Therefore, if the SWR measurement is repeated at the same frequency after connecting card 122 and/or circuit 120, the SWR reading for connected system 150 will be higher than for disconnected case as measured with disconnected system 100.

In certain embodiments, if continuity exists through the connector pair A and B 126/154, the SWR value for connected system 150 will be significantly larger than for disconnected system 100. The observation of either a “small” or “large” SWR value is an indication that connectors A and B are either “disconnected” or “connected”, respectively. In certain embodiments a small SWR would be approximately 1 to 2, while a large SWR would be approximately two or more times greater than the small SWR. The larger SWR value is because the conducting path PL_{C} 160 in connected system 150 is different from the disconnected conducting path length PL_{D} 130 in disconnected system 100. If the SWR of the connected system 150 roughly equals the SWR of the disconnected system 100 in step 110, the electrical connectors A and B 124/154 are not connected, since the length of the conduction path (PL) has not changed by any significant margin (i.e., PL_{D} 130 is approximately equal to PL_{C} 160).

In certain embodiments, step 220 includes being provided one or more additional electrical devices to form connected system 150 (see, e.g., FIG. 1B). In some embodiments, step 220 may include physically connecting disconnected system 100 to a second electrical device 152 to form connected system 150, and/or to a plurality of other electrical devices (not shown). The devices may be any electrical interconnect, such as a backplane, circuit card, or cable. In some embodiments, step 220 includes mating circuit 120 to second electrical device 152 via connectors A and B 126/154. In certain embodiments, the mating of system 100 with device 152 can be via a conductive cable (not shown) that electrically connects system 100 with device 152. In certain exemplary embodiments this can be via a connection between circuit 120 and device 152. In yet other embodiments, this connect can occur when a component of system 100 and second electrical device 152 have male or female connectors and each are plugged into corresponding male or female connectors of a backplane (shown in FIG. 1B as device 152). In this exemplary embodiment circuit card 122 seats in backplane 152 through the mating connectors A and B 126/152 to form exemplary connected system 150.

In certain exemplary methods, the radio frequency used to measure the SWR of disconnected system 100 in step 210 is inputted into connected system 150 (as shown in FIG. 1B, for example). The SWR value of connected system 150 is measured. In some embodiments, the radio frequency generator 114 and standing wave ratio meter 112 can be the same as used to measure the SWR of disconnected system 100 in step 210. In other embodiments, the user adjusts the radio frequency generator 114 to the frequency used to measure the SWR in step 210. In yet other embodiments, the user may connect disconnected system 100 with one or more electrical devices (as shown in FIG. 1B for example) and repeat step 220.

In some embodiments, step 230 includes recording the SWR of disconnected system 100 in step 210 and recording the SWR of the connected system 150 in step 220. In other embodiments, the SWR measurements may be automatically recorded on a recording device, such as a computer (not shown). In yet other embodiments, the SWR meter may automatically record the SWR values.

In some embodiments, step 240 includes noting the difference between the SWR of disconnected system 100 in step 210 and that of connected system 150 in step 230. In some embodiments, multiple SWRs of their respective connected system(s) 150 may be compared to the control SWR of disconnected system 100. If the SWR of connected system 150 is much larger than the SWR of disconnected system 100, electrical continuity is positively established throughout the system, since when the connector 126 on circuit card 122 is connected, the electrical path length changes to conducting path length PL_{C} 160 and the resonant frequency of conducting path length PL_{C} 160 will be different than the disconnected conducting path length PL_{D} 130 of disconnected system 100. In certain embodiments a small SWR can be approximately 1 to 2, while a large SWR can be approximately two or more times greater than the small SWR.

FIG. 3 illustrates another embodiment of a method 300 for testing the continuity of electrical interconnects. Method 300 contemplates determining if two or more electrical devices have electrical continuity when interconnected. The electrical devices may be any type of electrical device or component known in the art, including but not limited to a circuit board, a circuit card, backplanes, or similar devices. In the exemplary methods used with the embodiments of FIGS. 1A and 1B, for example, certain elements of systems 100 and 150 are treated as antennas. This exemplary method includes step 310 where the system to be tested is disconnected, forming disconnected system 100. In step 320 continuity tester 110 is electrically connected to system 100, and in step 330 an RF signal is applied to system 100 along a first disconnected path length PL_{D} 130. In step 340 the RF signal is adjusted to achieve a minimum disconnected SWR_{D} in disconnected system 100. In certain embodiments the minimum SWR_{D} is typically between 1 and 2, although in other embodiments the minimum SWR_{D} can be higher. In step 350 the minimum SWR_{D} and the frequency at which the minimum SWR_{D} is achieved are recorded. Certain embodiments of method 300 have multiple conducting paths, which can also be tested. In these embodiments steps 310-350 are repeated for additional conducting paths, and in certain of these embodiments a switch 128 is used to change to a different conducting path to perform one or more of steps 310-350.

In step 360, disconnected system 100 is connected to one or more devices to form connected system 150. The devices may be any electrical interconnect, such as a backplane, circuit card, or cable. In some embodiments, step 360 includes mating circuit 120 to second electrical device 152 via connectors A and B 126/154. In other embodiments, the mating of system 100 with device 152 can be via a conductive cable (not shown) that electrically connects system 100 with device 152. In certain exemplary embodiments this can be via a connection between circuit 120 and device 152. In yet other embodiments, this connect can occur when a component of system 100 and second electrical device 152 have male or female connectors and each are plugged into corresponding male or female connectors of a backplane (shown in FIG. 1B as device 152).

In step 370 an RF signal is applied to connected path length PL_{C} 160. In some embodiments the RF signal is the same frequency as the RF signal used in step 340, but it need not be. In step 380 a connected SWR_{C} from the RF signal applied in step 370 is recorded and compared to the disconnected SWR_{D} recorded in step 350. If SWR measurements are performed at the same frequency in steps 350 and 380, different SWR values will be observed if continuity exists through at least one of circuit of connected system 150. If the connected SWR_{C} is much greater than the disconnected SWR_{D} the tested path length is reported as “connected”. If the connected SWR_{C} is not much greater than the disconnected SWR_{D} the tested path length is reported as “disconnected”. In certain embodiments a small SWR can be approximately 1 to 2, while a large SWR can be approximately two times or more greater than the small SWR. In embodiments including multiple conducting paths, method 300 optionally repeats steps 360-380 for additional conducting paths, and in certain of these embodiments a switch 128 is used to change to a different conducting path to perform one or more of steps 360-380. In step 390 the results are recorded.

The type of electrical interconnection is not limited when utilizing methods disclosed herein; the electrical devices may be electrically interconnected using any methods known in the art. The methods are suitable for determining electrical interconnection of any type of electrical connection that establishes or is intended to establish a conductive pathway. For example, in some embodiments, a first electrical device can be directly electrically attached to a second electrical device to establish electrical continuity. In some embodiments, the first electrical device can be physically mated to the second electrical device. In some such embodiments, the mating of the first and second electrical devices can occur when a male connector on the first electrical device is inserted into a female connector on the second electrical device. In other embodiments, the mating of the first and second electrical devices can be indirect, for example when a conductive cable is electrically connected to both the first and second electrical devices. In yet other embodiments, the mating of the first and second electrical devices can occur when both the first and second electrical devices have male or female connectors and each are plugged into corresponding male or female connectors on a backplane.

### CONCLUSION

It will be understood that the systems and methods described herein are exemplary only. Many additional changes in the details, materials, steps, and arrangement of parts, which have been herein described and illustrated to explain the nature of the subject matter, may be made by those skilled in the art within the principle and scope of the invention as expressed in the appended claims. The steps of the methods described above may be performed in any order unless the order is restricted in the discussion. Any element of any embodiment may be used in any other embodiment and/or substituted for an element of any other embodiment unless specifically restricted in the discussion.

What is claimed is:

1. A method of determining electrical continuity of electrical interconnects, the method comprising the steps of:
measuring a first standing wave ratio value when the electrical interconnects are disconnected;
measuring a second standing wave ratio value when the electrical interconnects are connected; and
comparing the first standing wave ratio value to the second standing wave ratio value, wherein electrical continuity is positively determined when the second standing wave ratio value is much larger than the first standing wave ratio value.

2. The method according to claim 1, further comprising the step of selecting a radio frequency for the measurement of the first standing wave ratio value and the second standing wave ratio value.

3. The method according to claim 2, wherein the step of selecting a radio frequency includes selecting the radio frequency so that the first standing wave ratio is minimized.

4. The method according to claim 3, wherein
the radio frequency is selected to be a matched frequency of an antenna having a specified length, and
a circuit card associated with the electrical interconnects has a conducting path the same length as the antenna.

5. The method according to claim 2, further comprising the step of adjusting the radio frequency after the step of measuring the first standing wave ratio.

6. The method according to claim 1, further comprising the steps of
measuring a third standing wave ratio when an additional electrical interconnect is connected to said electrical interconnects; and
comparing the third standing wave ratio to the first standing wave ratio,
wherein electrical continuity is positively determined when the third standing wave ratio value is much larger than the first standing wave ratio value.

7. The method according to claim 1, wherein the step of comparing includes
recording the first standing wave ratio and the second standing wave ratio,
recording a comparison value,
converting the comparison value into a result, and
reporting the result.

8. The method of claim 4, wherein the circuit card connects to a single connector connected to a plurality of electrical interconnect paths.

9. The method of claim 8, wherein at least one of the plurality of electrical interconnects connects with a backplane connecting with at least one other circuit card.

10. A system for determining an electrical continuity of electrical interconnects, the system comprising:
a first electronic device having a first electrical connector;
a second electronic device having a second electrical connector configured to be electrically connected to the first electrical connector to establish electrical continuity;
a standing wave ratio meter connected to one of the first electronic device and the second electronic device;
a radio frequency generator connected to the standing wave ratio meter; and
a controller including a processor and a memory storage device.

11. The system of claim 10, wherein an output of the radio frequency generator is adjustable.

12. The system of claim 10, further comprising a first electrical interconnect connecting the first electronic device to the second electronic device.

13. The system of claim 12, further comprising a connector connecting at least one of the first electronic device and the second electronic device to a plurality of electrical interconnect paths.

14. The system of claim 13, further comprising a backplane connected to at least one of the plurality of electrical interconnects.

15. The system of claim 14, further comprising at least one other circuit card connected to the backplane.

16. A method of determining electrical continuity of electrical interconnects, the method comprising the steps of:
measuring a first standing wave ratio value when the electrical interconnects are disconnected;
measuring a second standing wave ratio value when the electrical interconnects are connected; and
comparing the first standing wave ratio value to the second standing wave ratio value, wherein
electrical continuity is positively determined when the second standing wave ratio value is much larger than the first standing wave ratio value, and
there is access to only one end of a conducting path between the electrical interconnects.

17. The method of claim 16, further comprising the step of selecting a radio frequency for the measurement of the first standing wave ratio value and the second standing wave ratio value.

18. The method of claim 17, wherein the step of selecting a radio frequency includes selecting the radio frequency so that the first standing wave ratio is minimized.

19. The method of claim 18, wherein
the radio frequency is selected to be a matched frequency of an antenna having a specified length, and
a circuit card associated with said electrical interconnects has a conducting path the same length as the antenna.

20. The method of claim 19, wherein
the circuit card connects to a single connector connected to a plurality of electrical interconnect paths;
at least one of the plurality of electrical interconnects connects with a backplane connecting with at least one other circuit card;
the at least one other circuit card connects to the backplane; and
the single connector connects to a plurality of electrical interconnects on an opposite end of the backplane.
